(19) United States
(12) Patent Application Publication
(10) Pub. No.: US 2014/0160692 A1
(43) Pub. Date: Jun. 12, 2014

(54) METHOD FOR SURFACE DECORATION OF AN OBJECT WITH 3-DIMENSIONAL GEOMETRY AND THE OBJECT OBTAINED THEREFROM

(71) Applicant: PC CONCEPTS LIMITED, North Point (HK)

(72) Inventor: Ping Cheung Michael Lau, North Point (HK)

(73) Assignee: PC CONCEPTS LIMITED, North Point (HK)

(21) Appl. No.: 14/098,166

(22) Filed: Dec. 5, 2013

Related U.S. Application Data
(60) Provisional application No. 61/734,452, filed on Dec. 7, 2012.

(51) Int. Cl. H05K 7/00; H05K 3/36

(52) U.S. Cl. CPC H05K 7/005; H05K 3/36
USPC 361/736; 29/428

(57) ABSTRACT

The present invention provides a method for surface decoration of a three-dimensional object with ease. In one embodiment of the invention, a planar construction article that is foldable into the object is utilized. In another embodiment of the invention, multiple angle plates that are assembled into the object are utilized. The surface decoration process is carried out before the planar construction article is folded or before the angle panels are assembled together thereby to significantly simplify the decoration process of object faces in different orientations. The invention also provides a three-dimensional object obtained from the methods of the invention.

### RELATED APPLICATION

This non-provisional application claims priority from the provisional application No. 61/734,452 filed on Dec. 7, 2012, the disclosures of which are incorporated herein by reference in their entirety.

### FIELD OF THE INVENTION

This invention relates generally to the field of surface decoration of a three-dimensional object, and more particularly, to a method for decorating one or more faces of a three-dimensional object with ease and simplified procedures, and also to an object obtained from the method.

### BACKGROUND OF THE INVENTION

RFID (radio frequency identification) and capacitive sensing technologies are commonly applied to a wide range of applications now-a-days. While the fundamental operation principle is different between the RFID and capacitive sensing technologies, the RFID electronic circuit always requires some kinds of an antenna for the RF signals and a capacitive sensing circuit always requires some kinds of a capacitive sensor for input detection. There may be different production methods for the RF antenna circuit and the capacitive sensor circuit, but typically the antenna circuit and the capacitive sensor circuit can be produced by printing the antenna circuit and/or the capacitive sensing circuit using conductive ink onto a flat substrate, such as a thin plastic film. When it is necessary to apply either the RFID and/or capacitive sensing technologies to a 3-dimensional object, such as a cube, the typically method is to install separate antenna and/or capacitive sensor on each of the cube faces.

A typical method for constructing a plastic cube in the art is the use of injection molding. In the injection molding method, the plastic cube can be constructed using two separate injection-molded plastic piece-parts which can then be assembled together by means of, such as solvent bonding, sonic welding, mechanical snap joins and/or screws to form the complete cube. The advantage of the injection molding method is that the cube is hollow inside and easy to structurally provide an opening when the part is molded and formed to facilitate the installation of an electronic circuit assembly and/or other mechanical assemblies into the cube if desired.

To visually identify the six individual cube faces of a cube, the typical method is to apply labels with adhesive backing and printed markings, such as alphabets and/or numbers, onto the individual cube face respectively. Alternatively, the marking for each cube face can be directly imprinted onto the different cube faces using for example a spraying or hot stamping process. Because there are multiple cube faces in different orientations, generally it takes separate steps and/or processes to apply the marking for each cube face using either the typical methods of applying self-adhesive labels or the direct imprint. Since the markings produced by the above methods are on the outer faces of the cube, the markings can be subjected to normal wears and tears during normal uses and could become scratched easily, not to mention the additional challenge to ensure the correct marking is applied onto the correct cube face and to properly align a label or an imprint squarely onto each of the cube faces.

By using the injection molding method, the markings are provided as a part of the cube and are in the same color as the cube itself. To enhance the readability of the inherently formed markings on the individual cube faces, it may still require additional decoration processes.

In the recent years, in-mold labeling has become a popular decoration process and is well known in the prior art for both injection-molded and blow-molded plastic parts. The in-mold labeling method is basically a decoration process that involves pre-printing the required artwork or pattern on a flat plastic thin film, followed by the application of a layer of heat activated glue, for example, on top of the printed artwork. The flat plastic thin film is then cut into the desired contour outline to become the in-mold label which is then put into either a blow mold or an injection mold for molding with the plastic object. Upon completion, the in-mold label becomes an integral part of the injection-molded or blow-molded object. Because the in-mold label is a flat printed plastic thin film, it is typically intended for molding and hence attached onto the relatively flat plastic surface without any 3-dimensional geometry.

When the in-mold labeling method is applicable to the 3-dimensional object, the flat printed plastic thin film would fail to spontaneously and voluntarily to conform itself to take the shape and contour of the 3-dimensional object. To overcome the above problem, the additional processes, for instance pre-forming the flat printed in-mold label to closely take the size and shape of the 3-dimensional object by means of a thermo-vacuum or other appropriate process, are required. The pre-formed in-mold label is then put into the mold for the 3-dimensional object for molding together with molten plastic in the mold to produce the 3-dimensional object with the in-mold label attached to it.

The above-mentioned method for applying the in-mold label for the 3-dimensional object however is inadequate for the cube construction, because the in-mold label needs to be thermo-vacuum pre-formed and trimmed in order to take the 3-dimensional size and shape to closely match the size and shape of the 3-dimensional object. Further, the 3-dimensional object consists of two molding parts, and therefore production of two separate in-mold labels is needed. The two molding parts are assembled together to form a complete cube after the two in-mold labels are attached to the two molding parts.

As can be seen from the above, it is clear that generally a plurality of steps and multiple processes are required to decorate the faces of the 3-dimensional cube structure in different orientations. Therefore, there is a need for a method for constructing a three-dimensional object, for example a cube structure, which enables to simplify the decoration and assembly process used to decorate the different faces of the three-dimensional object for example using a single step, and which eliminates the need of pre-forming and trimming the in-mold label to adapt for the 3-dimensional object as in the prior art.

### SUMMARY OF THE INVENTION

The present invention has been developed to fulfill the needs noted above and therefore has a principle object of the provision of a method for facilitating surface decoration of a three-dimensional object in one-step.

Another object of the invention is to provide a method for surface decoration of a three-dimensional object which is significantly more economical and convenient to operate than the methods for decorating surfaces of the three-dimensional object known in the prior art.

A yet object of the invention is to provide a method for surface decoration of a three-dimensional object which allows for decoration of inner and outer faces of the object.

These and other objects and advantages are satisfied by the invention. Thus, a first aspect of the invention is to provide a method for surface decoration of an object with 3-dimensional geometry, which takes advantage of a typical printing method, for example, to print the desired patterns including an antenna or a circuit pattern onto different faces of the three-dimensional object simultaneously. The method comprises the steps of:

providing an article of substantially planar construction which is able to form the 3-dimensional object in its folded position and to expand to a substantially planar construction in its unfolded position;

decorating one or more section areas of the planar construction article in its unfolded position;

folding the decorated planar construction article to form the 3-dimensional object with the decorated one or more section areas configured as one or more faces of the 3-dimensional object, respectively; and

providing constraining means for constraining the planar construction article in its folded position to retain the 3-dimensional geometry.

According to this method, each two adjacent section areas of the planar construction article may have a fold line or may be connected by a hinge so that all the section areas form together the planar construction article and each of the section areas is folded along the respective fold line or hinge to form the faces of the 3-dimensional object.

The decorating step comprises applying a first layer of surface identification markings or decorations, and/or comprises silk screening a second layer of conductive pattern, for example electronic antenna, on the first layer. Alternatively, the conductive pattern layer may be silk screened on the one or more section areas of the planar construction article in its unfolded position. It is possible to attach an electronic assembly onto the 3-dimensional object in a manner that the electronic assembly is electrically coupled to the conductive pattern for the purpose of electrical connection.

In order to facilitate the installation of the electronic assembly or component, it is advantageous to provide at least one extra foldable panel which is a part of the planar construction article. The extra panel is preferably disposed diagonally inside the 3-dimensional object in the folded position of the article. The extra foldable panel may be decorated or provided with an electronic assembly for example a PCB module at the same time of decorating other section areas of the planar construction before the planar construction article is folded.

According to the invention, the planar construction article may be selected from cut or stamped paper sheet, cardboard, plastic sheet, flexible metal sheet, and molding parts.

In order to provide ease and convenience of making conductive connection between the circuits printed on two opposite face sides of the object (i.e. the outer and inner sides of the object face), it would be beneficial to have the two opposite sides of the face to become conductive with each other side. Thus, a second aspect of the invention is to provide a method for surface decoration of an object with 3-dimensional geometry, comprising the steps of:

providing at least two angle panels which are assembled to form the 3-dimensional object, the angle panels each having at least one first connection member;

decorating one or more surfaces of the angle panels;

assembling the decorated angle panels to form the 3-dimensional object with the decorated panels configured as faces of the 3-dimensional object, respectively; and

providing constraining means for constraining the 3-dimensional object to retain the 3-dimensional geometry, the constraining means having a plurality of second connection members engageable with the first connection members of the angle panels.

It would be appreciated that two opposite sides of each face may be made conductive with each other side, and/or conductive respectively.

In one preferred embodiment of the invention, the angle panel is provided as a L-shaped construction, and three of such L-shaped panels are assembled to form a cube. Before the L-shaped panels are assembled together, each of them is partially or fully subject to electroplating of a conductive coating such that opposite faces of each L-shaped panel are electrically conductive with each other side or conductive respective, according to the actual needs or applications.

According the second aspect of the invention, the method comprises directly disposing preferably diagonally an electronic assembly for example a PCB module inside the three-dimensional object for electrically coupling to at least one of the angle panels.

As an alternative, at least one extra panel may be provided inside the 3-dimensional object for electrically coupling to at least one of the angle panels to carry the electronic assembly or the electronic component so that the latter may be electrically coupled to the conductive angle panel

A third aspect of the invention is to provide an object with 3-dimensional geometry comprising:

at least two angle panels which are assembled to form the 3-dimensional object, the angle panels each having at least one first connection member;

one or more surface decorations formed on one or more surfaces of the respective angle panels, wherein said one or more surface decorations are applied before the assembling of the angle panels;

means for constraining the angle panels to retain the 3-dimensional geometry, the means for constraining having at least one second connection member engagable with the at least one first connection member of the angle panel thereby to enable the engagement of the angle panel with the means for constraining.

A four aspect of the invention is to provide an object with 3-dimensional geometry comprising:

an article of substantially planar construction which is able to form the 3-dimensional object in its folded position and to expand to a substantially planar construction in its unfolded position;

one or more surface decorations formed on one or more faces of the 3-dimensional object, wherein said one or more surface decorations are applied onto one or more section areas of the planar construction article in its unfolded position, and said one or more section areas configured as the one or more faces of the 3-dimensional object in the folded position, respectively; and

means for constraining the planar construction article in its folded position to retain the 3-dimensional geometry.

In contrast to the surface decoration of different faces of an object in the prior art where multiple steps and processes are required, the foldable planar construction article of the first aspect of the invention is utilized, which allows for decoration of different faces simultaneously thereby to save time and reduce operational costs. After the decoration process, the planar construction article is folded to form the three-dimensional object. While in the second aspect of the invention, the angle panels such as L-shaped panels are provided to construct the three-dimensional object using a constraining means, and the L-shaped panels are electroplated with a conductive coating such as a metallic coating before they are assembled into the three-dimensional object, such that the L-shaped panels are fully or partially conductive. Decoration of the planar construction article or the L-shaped panels is exceedingly simple owing to the fact that the planar flat surface allows the use of a typical printing method to print, the desired patterns or the L-shaped panels can easily be electroplated. Therefore, the surface decoration methods according to the invention are relatively simple in operation, low in cost and fast to implement, and there is considerable variability in the printed conductive patterns.

To have a better understanding of the invention reference is made to the following detailed description of the invention and embodiments thereof in conjunction with the accompanying drawings.

### BRIEF DESCRIPTION OF THE DRAWINGS

FIG. 1A is an article having the basic planar construction that can be folded into a 3-dimensional object according to a first embodiment of the invention.

FIGS. 1B and 1C are perspective views showing how to fold the article of FIG. 1A into the 3-dimensional object.

FIG. 2A is an article having the planar construction that can be folded into a 3-dimensional object according to a second embodiment of the invention.

FIG. 2B and 2C are perspective views showing how to fold the article of FIG. 2A into the 3-dimensional object.

FIG. 3 shows that the foldable article of planar construction of FIGS. 2A to 2C further comprises at least one decoration layer applied onto one or more section areas in the unfolded position, which section areas are configurable as the faces of the 3-dimensional object.

FIG. 4 shows that the foldable article of planar construction of FIGS. 2A to 2C further comprises a silk screen printed conductive circuit layer applied onto one or more section areas in the unfolded position, which section areas are configurable as the faces of the 3-dimensional object using conventional printing method.

FIG. 5 shows a perspective view that the foldable article of planar construction of FIGS. 2A to 2C further comprises an electronic PCB module mounted onto the section area of the extra foldable panel.

FIG. 6 is an example of means for constraining the article of FIGS. 1A or 2A in their respective folded position to retain the 3-dimensional geometry.

FIG. 7A shows how to retain the 3-dimensional geometry of the object using the means for constraining of FIG. 6.

FIG. 7B shows the object of FIG. 7A is retained in place.

FIG. 8 is a perspective view of a L-shaped panel constructed according to a third embodiment of the invention.

FIG. 9 is a perspective view of the L-shaped panel provided with protrusions for engageable with a PCB module.

FIG. 10 is a perspective view of the engagement of the L-shaped panel and the PCB module.

FIG. 11 is a perspective view of an exemplary means for constraining the L-shaped panels to construct a cube.

FIG. 12 is a perspective view of one L-shaped panel in operative engagement with the PCB module and being constrained by the means for constraining.

FIG. 13 is a perspective view of a cube formed by constraining three L-shaped panels.

In the various figures of the drawings, like reference numbers are used to designate like parts.

### DETAILED DESCRIPTION OF THE PREFERRED EMBODIMENTS

While this invention is illustrated and described in preferred embodiments, the object with various surface decorations may be constructed using the methods of invention in many different configurations, sizes, forms and materials.

For the sake of clarity and convenience, “cube” is taken herein as one example of the three-dimensional object. It would be appreciated that any other three-dimensional objects are applicable.

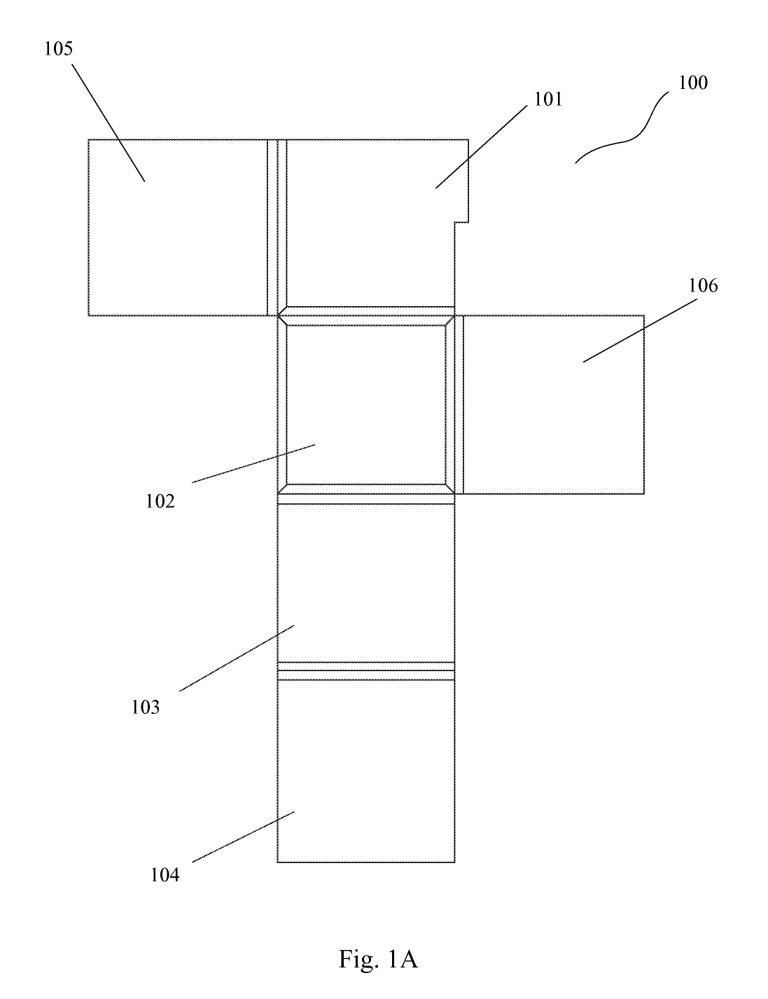

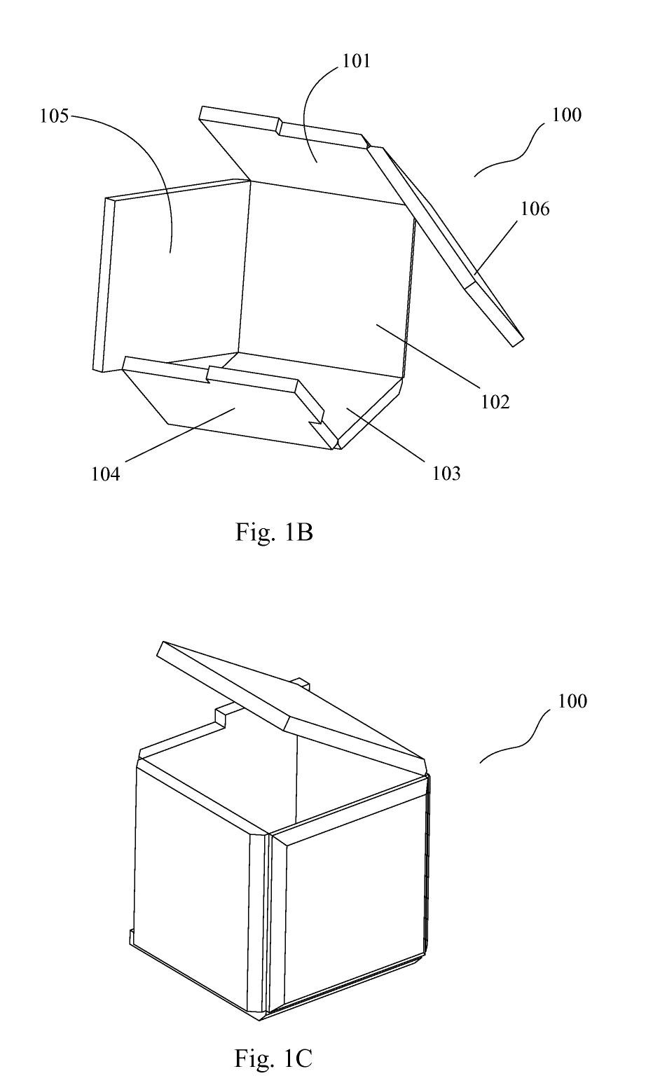

Referring now to the drawings, FIGS. 1A to 1C provide a foldable article 100 having the basic planar construction constructed consistent with a first embodiment of the present invention. In this embodiment, the planar construction article 100 comprises first to fourth section areas 101, 102, 103, 104 aligned together, fifth section area 105 extending from and perpendicular to the first section area 101, and sixth section area 106 extending from and perpendicular to the second section area 102. All the six section areas are in the substantially same planar plane, and each two adjacent section areas have a fold line or a hinge along which they can be folded up. The six section areas 101-106 together may be easily folded up to construct a cube, with the section areas 101-106 configured as the respective faces of the cube, as shown in FIGS. 1B and 1C.

The planar construction article 100 is basically flat in its unfolded position, and all the section areas are in the same plane before they are folded to form the cube. Therefore, it is possible to use a typical printing method to decorate one or more section areas simultaneously. For example, surface identification markings for the specific faces of the cube or aesthetic decoration patterns may be applied on the section areas of the planar construction article. It is also possible to silk screen conductive patterns, for example, any desirable type of antenna and/or capacitive sensor circuit patterns onto one or more section areas at the same time before the folding operation. After the decoration patterns or the conductive patterns are printed on the section areas, the sections areas are then folded into a cube where the printed patterns necessarily are shown on the required faces of the cube.

Any suitable material is possible for the planar construction article. Preferably, the material may be selected from the group consisting of cut or stamped paper sheet, cardboard, plastic sheet, flexible metal sheet, and molding part.

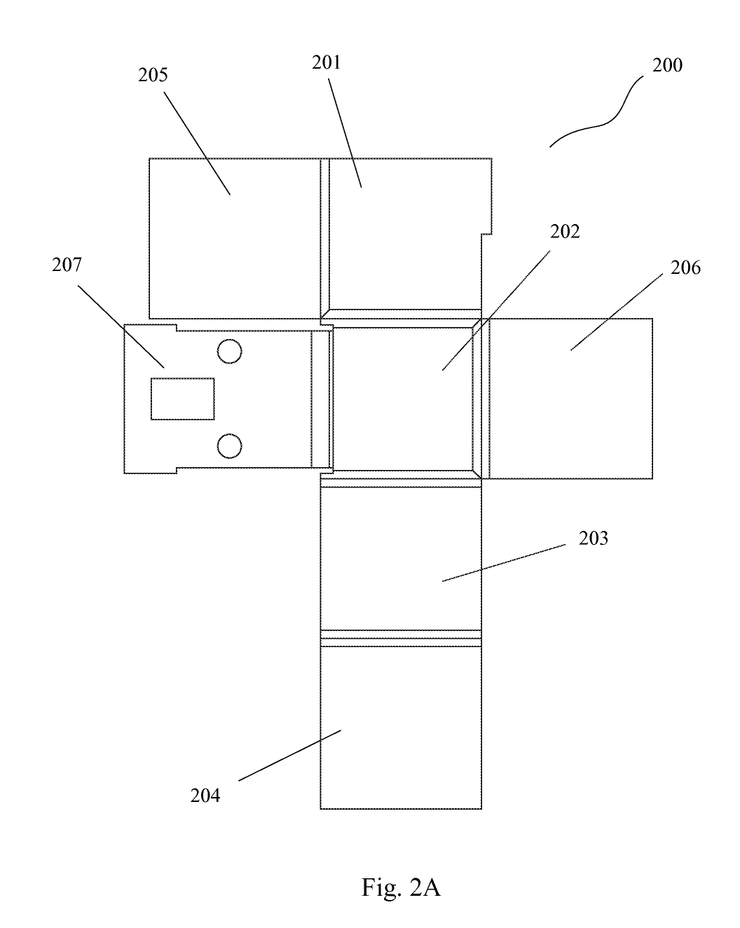

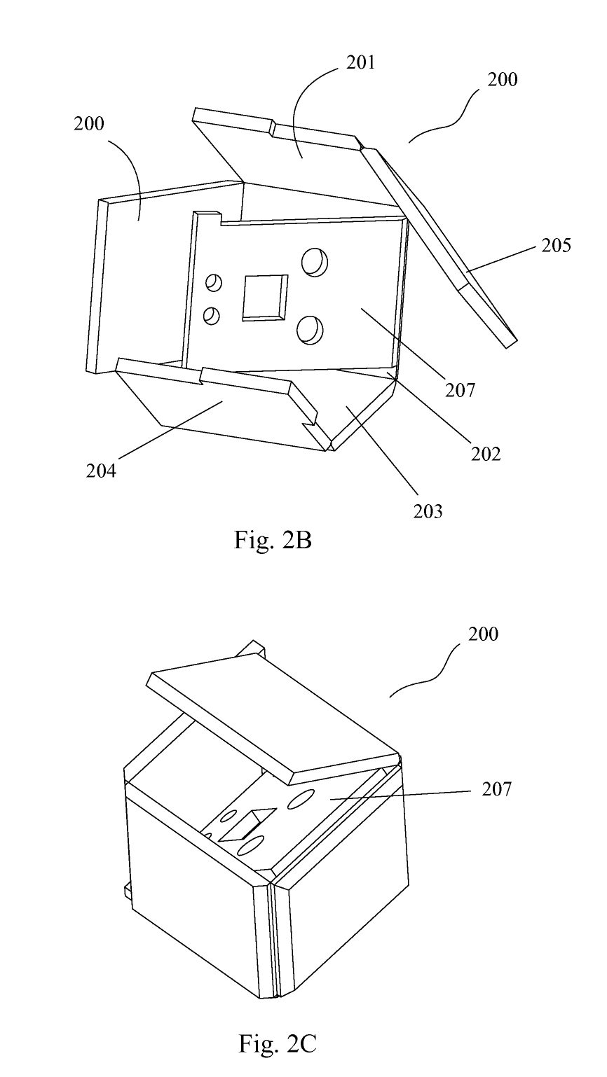

Turning to FIGS. 2A to 2C, there is illustrated a foldable article 200 having the planar construction constructed consistent with a second embodiment of the present invention. Like the foldable article 100 of the first embodiment discussed above, the planar construction article 200 comprises first to sixth section areas 201, 202, 203, 204, 205 and 206. However the foldable article 200 further comprises an extra section area 207 extending from the second section area 202 in the plane where the other section areas are located. The extra section area 207 is located to be opposite to the sixth section area 206 in this embodiment. Similarly, there is a fold line or a hinge between the extra section area 207 and the second section are 202 so that the extra section area 207 is folded along the fold line or the hinge to be generally disposed diagonally inside the cube when the planar construction article 200 is folded to form the cube. If desirable, the extra section area 207 may be subject to the decoration process at the same time of decorating the other six section areas 201-206. The extra section area 207 is provided to facilitate the installation of an electronic assembly or component (e.g. a printed circuit board, PCB) which is electrically coupled to the printed conductive patterns on the planar construction article 200 before the folding up.

The extra section area 207 may comprises through holes 208 engagable with corresponding protrusions (not shown) formed on the second section area 202, thereby to secure the extra section area 207 in place inside the cube.

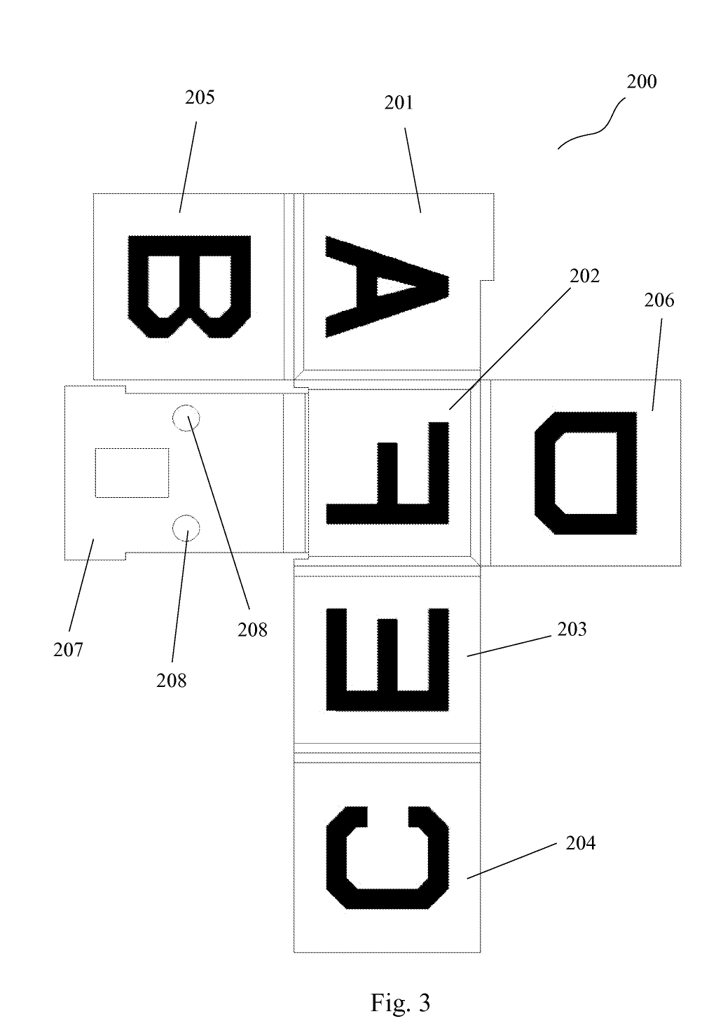

FIG. 3 illustrates an example of decoration pattern. As illustrated, a capital letter used as a surface identification of the face of the cube is applied to each of the section areas 201-206 in the unfolded position of the article 200. Because of the planar construction, all the six capital letters can be printed simultaneously, which greatly simplifies the decoration of different faces of a three-dimensional object.

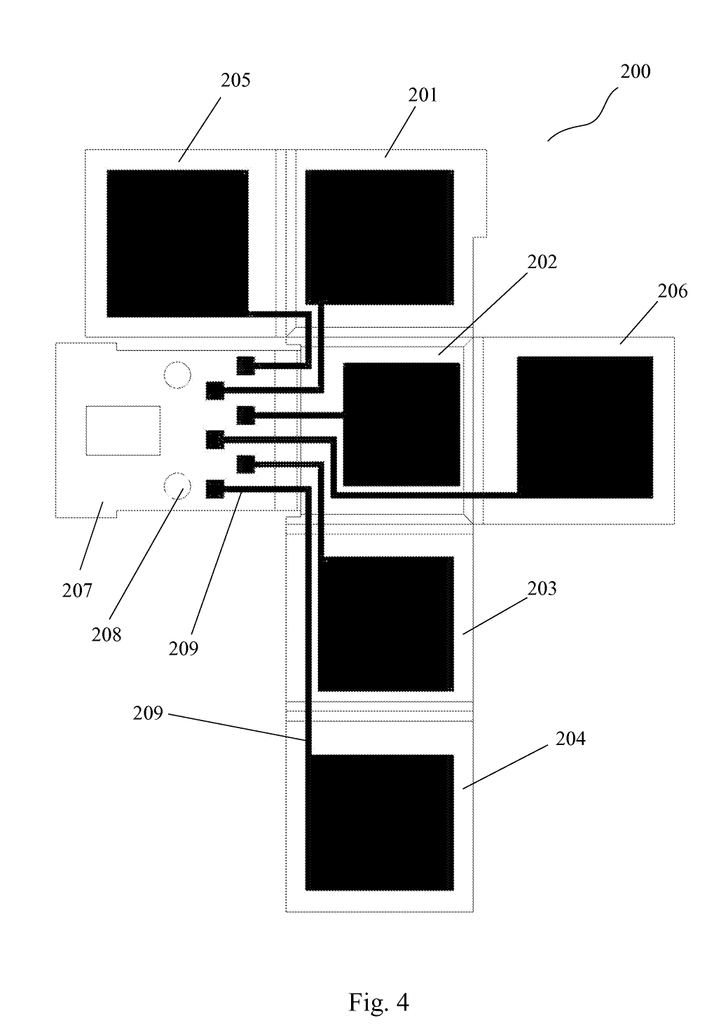

FIG. 4 illustrates another example of decoration pattern which is a silk screen printed conductive circuit layer 209 applied onto one or more section areas configurable as the faces of the object employing the conventional printing method. As discussed above, the silk screen printed conductive circuit 209 is applied when the article 200 is in the unfolded position to ease the imprinting of the conductive circuit on different faces of the cube. As shown in this figure, the printed conductive circuit extends to the extra section area 207 so that the conductive circuit is applicable to all the section areas 201-207.

FIG. 5 illustrates an electronic module or an electronic assembly (e.g. PCB) 210 attached to the extra section area 207 of FIG. 4 in a manner that the electronic module or assembly is electrically coupled to the conductive circuit 209 printed on the extra section area 207 and thus to the first to sixth section areas 201-206. The attachment of the electronic assembly may be achieved by any suitable method known in the art.

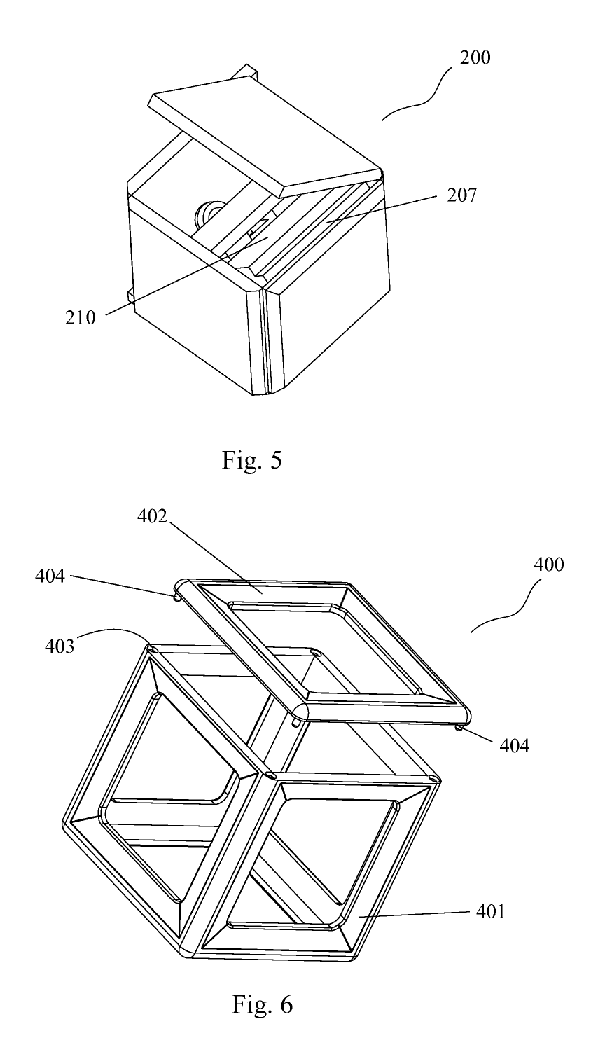

To properly constrain the cube in place, a cubic frame 400 shown in FIG. 6 is provided to constrain the cube folded by the foldable article 100 so that the folded cube retains the three-dimensional geometry. The cubic frame 400 comprises a cubic body 401 with opened top and a square cover 402 adapted to be detachably placed over the opened top of the cubic body. Four tabs 404 extend downward respectively from the four corners of the square cover 402, and four notches 403 are formed at the corners of the opened top of the cubic body 401 such that the cover 402 and the cubic body 401 are assembled together in a snap fit manner for frequent assembly and disassembly. Each face of the cubic body 401 and the cover 402 are hollowed out to expose the section areas of the folded cube.

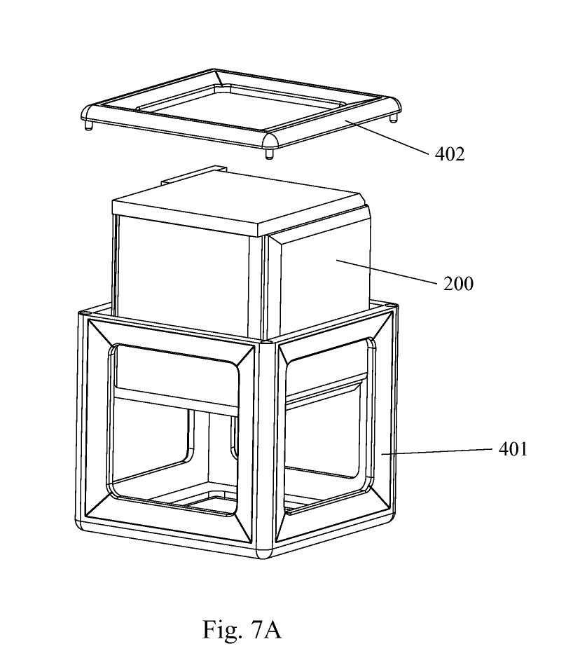

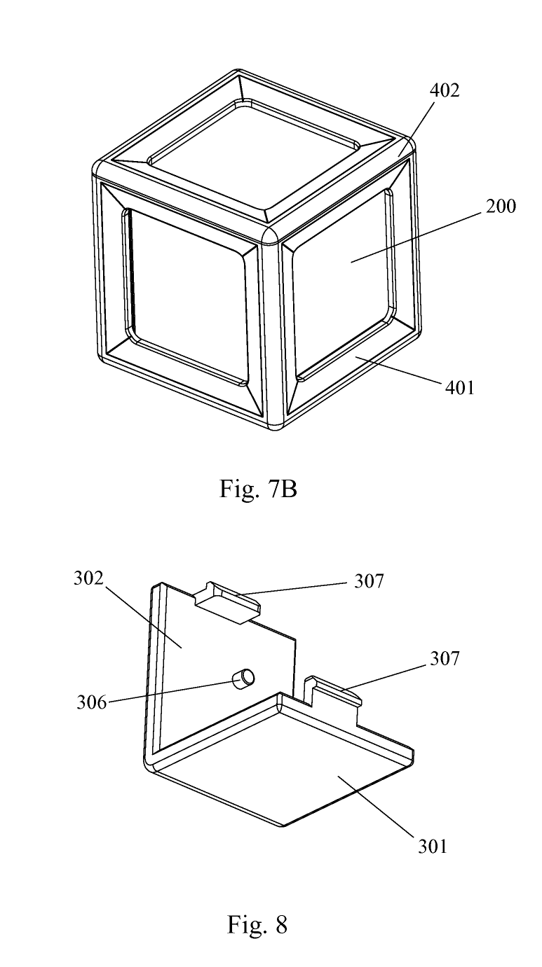

Referring to FIGS. 7A and 7B, there is illustrated that the cubic frame 400 is sized to snugly receive and constrain the folded cube in place.

The planar construction articles 100, 200 discussed above provides the ease and convenience of printing the required patterns for example antenna and/or capacitive sensor circuit onto two opposite sides of each of different cube faces simultaneously. However, in some occasions requiring a conductive connection between the opposite sides (i.e. outer and inner face sides) of each cube face, it may take some additional processes to achieve this purpose. FIGS. 8 to 13 provide a much simple process to make the two opposite sides of each cube face to be conductive with each other.

There is illustrated a L-shaped panel in FIG. 8. The L-shaped panel consists of two side panels 301, 302 at right angle. Each of the two side panels 301, 302 is provided with a built-in male or female joint 307 on its free end edge. The means for constraining the L-shaped panel is correspondingly provided with a built-in female or male joint. By snap fitting the snap-fittable joints of the L-shaped panel and the means for constraining to form an interlocked joint, the means for constraining is able to constrain the L-shaped panel in place. This will be described hereinbelow.

The L-shaped panel can be easily be electroplated with conductive coating such as a metallic coating using any method known in the art. In consideration of the fact that the electroplating process is well known and not an essence of the invention, it is not elaborated herein. According to the actual needs, the L-shaped panel can be fully or partially electroplated such that the entire L-shaped panel is conductive, or a desirable part of the L-shaped panel is conductive while the opposite two sides of the L-shaped panel remain conductive with each other. The partial electroplating may be carried out by masking the undesired part of the panel during and/or after the electroplating process. With the partial electroplating, any type of conductive patterns for example antenna and/or conductive circuit can be applied to the surface of the side panels 301, 302. A cube can be constructed by assembling three of the electroplated L-shaped panels after the electroplating process.

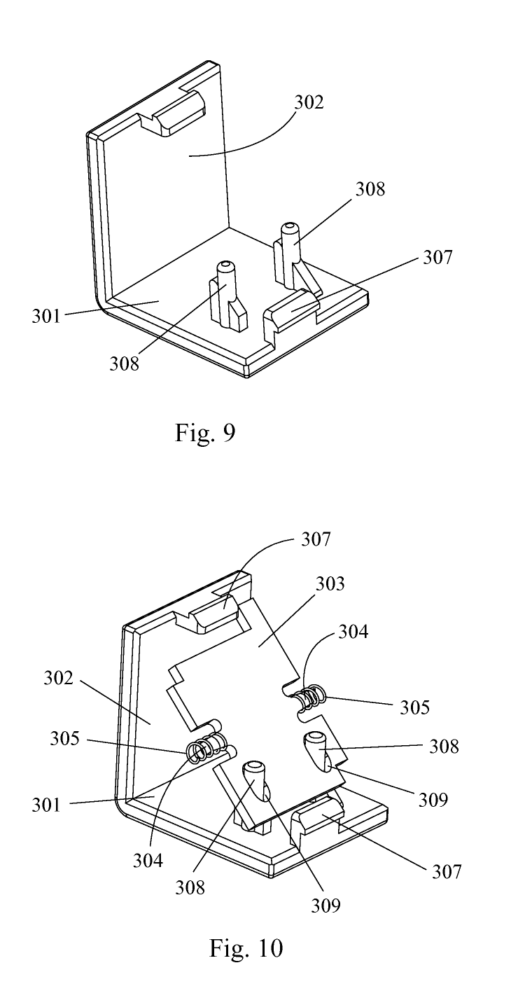

Now referring to FIG. 10, there is illustrated an electronic assembly such as a PCB module 303 in engagement with the L-shaped panel of FIG. 8. In this embodiment, the PCB module 303 is directly disposed diagonally in the cube without the need of any support or carrier. As shown in FIG. 9, two protrusions 308 in spaced relation extend from a surface of the side panel 301, while two through holes 309, which are positioned to correspond to the two protrusions 308, are provided on the PCB module 303 to allow the protrusions to pass therethrough, as shown in FIG. 10. The PCB module 303 is thus conductively engaged with the L-shaped panel.

In order to enable the PCB module 303 to be in conductive contact with the other two electroplated L-shaped panels that are not in engagement with the PCB module, an electrically conductive spring holder 304 is formed on each of two sides of the PCB module 303 that are facing the other two L-shaped panels. A conductive metallic compression spring 305 is held at one end by the spring holder 304, and the other end of the spring 305 would be compressed to come into conductive contact with one of said other two L-shaped panels and the PCB module when the three L-shaped panels are assembled together to form a cube which is constrained in place. A stub 306 is formed on the L-shaped panel to be in positional correspondence with the spring 305. The stub 306 is adapted to pass through the other end of the spring 305 in compressed state. The spring 305 is able to come into contact with said L-shaped panel in compressed status. In this way, the PCB module 303 is in contact with all the three L-shaped panels in a conductive manner. This enables the conductive connection of the PCB module with each of the electroplated L-shaped panels.

Of course, like the second embodiment described above, an extra panel (not shown) may be diagonally provided inside the cube to carry an electronic assembly or component for facilitating and allowing the conductive connection of the assembly or component with each of the electroplated L-shaped panels, if needed.

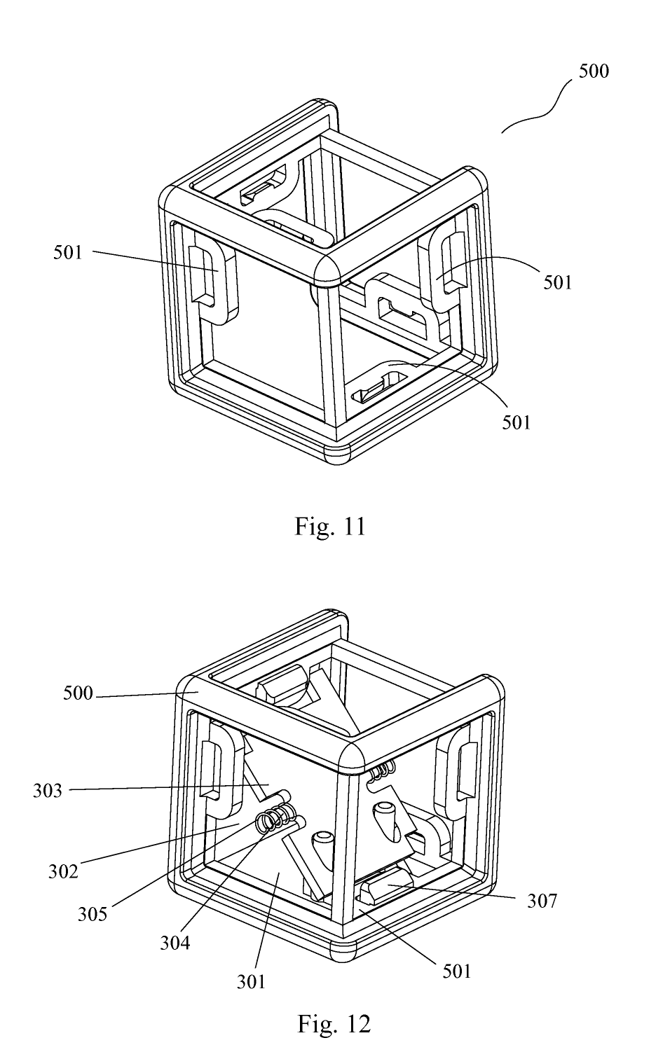

FIG. 11 illustrates an exemplary means for constraining the L-shaped panels to retain the three-dimensional geometry. In this embodiment, a cubic frame 500 is provided with each cube face being hollowed out to expose the surfaces of the side panels of the L-shaped panels, which surfaces are configurable as the cube faces when the panels are constrained. The cubic frame 500 is usually non-conductive, so each two panels would not be able to form conductive connection through the frame 500. This cubic frame 500 are formed with a plurality of snap-fittable female or male joints 501 which are able to create interlocked joints with the male or female joints 307 of the respective L-shaped panels, thereby to constrain the cube formed by the three L-shaped panels to retain the three-dimensional geometry.

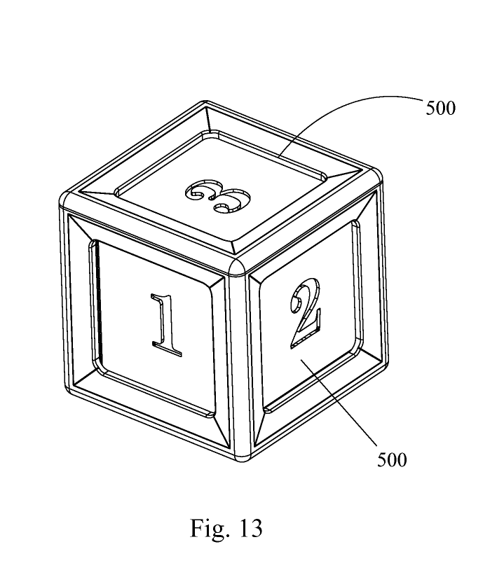

FIG. 12 illustrates the combination of the L-shaped panel and the PCB module 303 in FIG. 10 is constrained by the cubic frame 500, where the male joint 307 of the L-shaped panel is inserted into the female joint 501 of the frame 500 by snap fitting. FIG. 13 illustrates that a complete cube is constrained, where each face of the cube is decorated with a surface marker such as the numbers “1”, “2”, “3” and so on.

Due to the use of the planar construction article and the angle panel, the methods of the invention allow to decorate different faces of the three-dimensional object at the same time. This simplifies the decoration of the different faces. Another distinctive feature of the invention is to come up with the design of means for constraining the article or the angle panels to retain the three-dimensional geometry, the means for constraining is critical to accomplish the assembly of the three-dimensional object using the planar construction article or angle panels.

As described above, assembly and disassembly of the object of the invention is very easy. The invention thus provides methods for surface decoration of the three-dimensional object in one step, which are simple to implement.

While the embodiments described herein are intended as exemplary methods and objects, it will be appreciated by those skilled in the art that the present invention is not limited to the embodiments illustrated. Those skilled in the art will envision many other possible variations and modifications by means of the skilled person's common knowledge without departing from the scope of the invention, however, such variations and modifications should fall into the scope of this invention.

What is claimed is:

1. A method for surface decoration of an object with 3-dimensional geometry, comprising the steps of:
providing an article of substantially planar construction which is able to form the 3-dimensional object in its folded position and to expand to a substantially planar construction in its unfolded position;
decorating one or more section areas of the planar construction article in its unfolded position;
folding the decorated planar construction article to form the 3-dimensional object with the decorated one or more section areas configured as one or more faces of the 3-dimensional object, respectively; and
providing constraining means for constraining the planar construction article in its folded position to retain the 3-dimensional geometry.

2. The method of claim 1, wherein each two adjacent section areas of the planar construction article has a fold line or are connected by a hinge so that all the section areas form together the planar construction article and each of the section areas is folded along the respective fold line or hinge to form the faces of the 3-dimensional object.

3. The method of claim 1, wherein the planar construction article is selected from cut or stamped paper sheet, cardboard, plastic sheet, flexible metal sheet, and molding part.

4. The method of claim 1, wherein the decorating step comprises applying a first layer of surface identification markings or decorations.

5. The method of claim 4, wherein the decorating step comprises silk screening a second layer of conductive pattern, for example electronic antenna, on the first layer.

6. The method of claim 5, further comprising attaching an electronic assembly onto the 3-dimensional object in a manner that the electronic assembly is electrically coupled to the conductive pattern.

7. The method of claim 1, wherein the decorating step comprises silk screening conductive patterns on the one or more section areas of the planar construction article in its unfolded position.

8. The method of claim 1, further comprising the step of providing at least one extra foldable panel on the planar construction article, wherein said extra foldable panel forms a part of the planar construction in the unfolded position of the article and is disposed diagonally inside the 3-dimensional object in the folded position of the article.

9. The method of claim 8, further comprising decorating a section area of the extra foldable panel.

10. The method of claim 8, wherein the decorating step comprises applying an electronic assembly for example a PCB module onto the section area of the extra foldable panel.

11. A method for surface decoration of an object with 3-dimensional geometry, comprising the steps of:
providing at least two angle panels which are assembled to form the 3-dimensional object, the angle panels each having at least one first connection member;
decorating one or more surfaces of the angle panels;
assembling the decorated angle panels to form the 3-dimensional object with the decorated panels configured as faces of the 3-dimensional object, respectively; and
providing constraining means for constraining the 3-dimensional object to retain the 3-dimensional geometry, the constraining means having a plurality of second connection members engageable with the first connection members of the angle panels.

12. The method of claim 11, wherein the 3-dimensional object is a cube which is assembled by three angle panels provided as a L-shaped construction.

13. The method of claim 11, wherein the decorating step comprises applying an electrically conductive coating on the respective angle panels.

14. The method of claim 13, wherein the coating is applied by electroplating partially or fully the respective angle panels such that opposite surfaces of each of the angle panels are electrically conductive.

15. The method of claim 14, further comprising attaching an electronic assembly for example a PCB module onto the conductive angle panel.

16. The method of claim 1, further comprising the step of providing at least one extra panel on the 3-dimensional object for electrically coupling to one of the angle panels.

17. The method of claim 16, wherein the extra panel is disposed obliquely preferably diagonally inside the 3-dimensional object.

18. The method of claim 16, further comprising the step of electroplating partially or fully the extra panel such that the extra panel is conductive and adapted for electrically coupled to an electronic assembly.

19. The method of claim 1, comprising directly disposing preferably diagonally an electronic assembly inside the three-dimensional object for electrically coupling to at least one of the angle panels.

20. An object with 3-dimensional geometry comprising:
at least two angle panels which are assembled to form the 3-dimensional object, the angle panels each having at least one first connection member;
one or more surface decorations formed on one or more surfaces of the respective angle panels, wherein said one or more surface decorations are applied before the assembling of the angle panels;
means for constraining the angle panels to retain the 3-dimensional geometry, the means for constraining having at least one second connection member engagable with the at least one first connection member of the angle panel thereby to enable the engagement of the angle panel with the means for constraining.

21. The object of claim 20, wherein the angle panels are partially or fully electroplated with a conductive coating such that opposite surfaces of each of the angle panels are electrically conductive.

22. The object of claim 21, wherein the surface decorations comprise conductive patterns for example an electronic antenna formed on the one or more surfaces of the angle panels, or an electronic assembly and/or component is attached onto the one or more surfaces of the angle panels.

23. The object of claim 20, wherein the angle panel is provided as a L-shaped construction, and three L-shaped panels are assembled into the 3-dimensional object forming a cube.

24. The object of claim 20, further comprising an electronic assembly directly disposed preferably diagonally inside the three-dimensional object for electrically coupling to at least one of the angle panels.

25. The object of claim 24, wherein one or more protrusions extend from a surface of one of the angle panels, and the electronic assembly is provided with one or more holes configured to engage with the one or more protrusions in a manner that the electronic assembly is electrically coupled to said angle panel.

26. The object of claim 25, wherein the electronic assembly has at least one conductive element to allow for electrical coupling of the electronic assembly with at least one of the other angle panels.

27. The object of claim 20, further comprising an extra panel inside the 3-dimensional object for electrically coupling to at least one of the angle panels.

28. The object of claim 27, wherein the extra panel is disposed obliquely preferably diagonally inside the 3-dimensional object to carry an electronic assembly or an electronic component.

29. The object of claim 27, wherein the extra panel is electroplated partially or fully such that the extra panel is conductive.

30. An object with 3-dimensional geometry comprising:
an article of substantially planar construction which is able to form the 3-dimensional object in its folded position and to expand to a substantially planar construction in its unfolded position;
one or more surface decorations formed on one or more faces of the 3-dimensional object, wherein said one or more surface decorations are applied onto one or more section areas of the planar construction article in its unfolded position, and said one or more section areas configured as the one or more faces of the 3-dimensional object in the folded position, respectively; and
means for constraining the planar construction article in its folded position to retain the 3-dimensional geometry.

31. The object of claim 30, wherein the surface decorations comprise printed conductive patterns for example an electronic antenna formed on the one or more section areas of the planar construction article in the unfolded position.

32. The object of claim 31, further comprising an electronic assembly and/or component attached onto the 3-dimensional object in a manner that the electronic assembly and/or component is electrically coupled to the printed conductive pattern.

33. The object of claim 30, further comprising at least one extra foldable panel connectable to an edge of one of the faces of the object, said extra foldable panel forming a part of the planar construction in the unfolded position of the article.

34. The object of claim 33, wherein the extra foldable panel is disposed diagonally inside the 3-dimensional object in the folded position of the 3-dimensional object.

35. The object of the claim 33, wherein the extra foldable panel is decorated or printed with conductive patterns in the unfolded position of the planar construction article.
